(19) United States
(12) Patent Application Publication
(10) Pub. No.: US 2008/0006319 A1
(43) Pub. Date: Jan. 10, 2008

(54) PHOTOVOLTAIC AND PHOTOSENSING DEVICES BASED ON ARRAYS OF ALIGNED NANOSTRUCTURES

(76) Inventors: Martin Bettge, Urbana, IL (US); Stephan Burdin, Mahomet, IL (US); Scott MacLaren, Champaign, IL (US); Ivan Petrov, Champaign, IL (US); Ernie Sammann, Urbana, IL (US)

Correspondence Address: GREENLEE WINNER AND SULLIVAN P C, 4875 PEARL EAST CIRCLE, SUITE 200, BOULDER, CO, 80301, US

(21) Appl. No.: 11/758,599

(22) Filed: Jun. 5, 2007

Related U.S. Application Data
(60) Provisional application No. 60/810,901, filed on Jun. 5, 2006.
(60) Provisional application No. 60/811,033, filed on Jun. 5, 2006.

(51) Int. Cl. H01L 31/042; H01L 31/06

(52) U.S. Cl. 136/244

(57) ABSTRACT

Photovoltaic cells and methods for making photovoltaic cells are provided. The photovoltaic cells include a photoactive layer which includes an array of elongated vertically aligned nanostructures. The nanostructures include at least a first and a second semiconducting material. The photovoltaic layer may also include a transparent insulating material which serves a passivation function.

### CROSS-REFERENCE TO RELATED APPLICATIONS

This application claims the benefit of U.S. Provisional Applications 60/810,901 and 60/811,033, both filed Jun. 5, 2006, both of which are hereby incorporated by reference to the extent not inconsistent with the disclosure herein.

### ACKNOWLEDGEMENT OF GOVERNMENT SUPPORT

This invention was made with Government support under Contract Number DEFG02-91-ER45439 awarded by the U.S. Department of Energy (DOE). The Government has certain rights in the invention.

### BACKGROUND OF THE INVENTION

The invention is in the field of photovoltaic and photosensing devices, in particular devices which are based on arrays of aligned nanostructures of semiconducting materials. The invention also provides methods for making such devices.

Photovoltaic or solar cells convert solar energy into electrical energy. Conventional photovoltaics or solar cells contain layers of two types of semiconductor material. The junction between the layers may be a “homojunction” formed by two differently doped layers of the same basic material or a “heterojunction” formed from two materials which differ in their basic composition.

In a planar standard cell, it is possible to lose up to 35% of the incident light by front and back-side reflectances. To increase the absorptivity, surfaces can be modified and textured by wet-chemical etching resulting in pyramidic structures or inverted pyramids (Goetzberger et al., 1998, “Crystalline Silicon Solar Cells”, John Wiley, New York; Goetzberger, A. et al., 2003, Mater. Sci. Eng. R, 40, p1). In general, the increase in absorptivity is or can be due to: 1) destructive interference of front and back side reflectance and 2) scattering and diffraction of light of wavelengths longer than the texture feature size 3) gradual impedance match or equivalently a gradual match of the dielectric constants of the surrounding medium (air) and of the light absorbing material (here silicon). 4) multiple reflections in between high aspect ratio structures that act like black bodies reducing the amount of light leaving a cavity, eventually trapping the light 5) quantum confinement effects 6) size dependant and stress-induced band gap variations 7) excitation of surface plasmons.

U.S. Pat. No. 4,099,986 to Diepers reports a solar cell comprising a plurality of single crystal semiconducting whiskers. As referred to in the reference, whiskers are several microns in diameter and have lengths up to several centimeters. The surface of the whiskers is given a doping of the opposite type from the interior of the whisker, forming a p-n junction. The large surface area to volume ratio of the whiskers is stated to lead to a p-n junction in the cell of particularly large surface, resulting in a large increase of the quantum yield as compared to a plane surface. In addition, it is stated that the whiskers can absorb the radiation almost without reflection.

Ji et al. (Ji, C., et al, 2002, 29^{th} Conf. Proceedings IEEE-PVSC, p. 1314) report a solar cell design involving aligned silicon nanowires with n/p junctions. An indium-tin oxide (ITO) conductive antireflection coating embeds the nanowires and grid lines are deposited on the ITO layer.

U.S. Pat. No. 6,878,871 to Scher et al. reports nanostructure and nanocomposite based photovoltaic devices. The photovoltaic devices can include semiconductor nanostructures as at least a portion of a photoactive layer.

U.S. Pat. No. 6,852,920 to Sager et al. report solar cells comprising oriented arrays of nanostructures wherein two or more different materials are regularly arrayed and wherein the presence of two different materials alternates.

U.S. patent Publication 2006/0057360 to Samuelson et al. reports a solar cell array which includes nanostructures formed of branched nanowhiskers. The trunk nanowhiskers are formed of a first semiconductor material such as GaP and the second level nanowhiskers of a second semiconductor material such as GaAsP.

U.S. patent Publication 2007/0111368 to Zhang et al. report a photovoltaic structure with conductive nanowire array electrode.

U.S. Pat. No. 7,202,173 to Hantschel et al. report systems and methods for electrical contacts to arrays of vertically aligned nanorods.

Camacho et al. report carbon nanotube arrays for photovoltaic applications (Camacho et al., 2007, JOM, 3942). The carbon nanotubes form the back contact of the device and serve as a scaffold for the photoactive CdTe/CdS heterojunction.

### SUMMARY OF THE INVENTION

The present invention provides a photoactive layer for photovoltaic and photosensing devices. In the photoactive layer, solar to electrical energy conversion takes place in a nanostructured thin film including at least two kind of semiconducting materials. In an embodiment, the nanostructured thin film comprises an array of vertically aligned elongate nanostructures, the nanostructures comprising at least two kinds of semiconducting material. In an embodiment, the nanostructures are also laterally aligned. In an embodiment, the aligned nanostructures comprise silicon. The aligned nanostructures can produce high levels of light trapping and absorption for enhanced efficiency. Devices based on these structures are expected to be less sensitive to short charge-carrier lifetimes and high defect densities. Photovoltaic devices employing these aligned semiconductor-containing nanostructures can also use less semiconductor material than conventional devices, resulting in increased energy production per weight of semiconductor. For example, the invention can permit the same level of light absorption as obtained with a conventional device with less than 1/50^{th} the thickness of material. In addition, when the photoactive layer is about 50% dense, the amount of silicon needed will be approximately 1% of that required for a typical device.

In an embodiment, the nanostructures of the photoactive layer allow point contacts to be made at least one side of the layer. Point contacts can reduce carrier recombination at the semiconductor-contact interface.

In an aspect of the invention, the devices comprise a photoactive layer disposed between two electrical contact layers. The photoactive layer contains at least two different types of semiconducting materials. The two semiconducting materials possess different electronic workfunctions. For example, the two different types of semiconducting materials may be differently doped types of the same semiconductor material or two different semiconductor materials (which differ in their basic chemical composition). The interface(s) between the two different types of semiconducting materials enables the conversion of solar energy to electrical energy. Therefore, a nanostructured solar cell can be formed which includes nano-solar cells formed by each of these coated nanostructures.

The photoactive layer can be regarded as containing two arrays of elongated nanostructures. The longitudinal axis of the nanostructures is generally aligned parallel to the photoactive layer thickness. The secondary array comprises the at least two different semiconducting materials. The secondary array comprises a primary array which comprises the first semiconducting material, but does not include all the different semiconducting materials present in the secondary array. For example, when two semiconducting materials are present in the secondary array only the first semiconducting material is present in the primary array (although the nanostructures of the primary array may also comprise non-semiconducting materials). In an embodiment, at least part of the first semiconducting material is provided by the primary array.

Various forms of the photoactive layer elements are shown in FIGS. 1-4. FIGS. 1-4 illustrate that a photoactive layer containing two arrays; a secondary nanostructure array which combines the first (30) and second (40) semiconducting materials and a primary array which comprises the first semiconducting material but does not include the second semiconducting material. In FIGS. 1-4, the nanostructures of the first semiconducting material (30) form the primary nanostructure array. The primary nanostructure array may be contained within the secondary array, as illustrated in FIGS. 1-2.

The array nanostructures of the first semiconducting material can take a variety of shapes. In FIGS. 1-2, the nanostructures (30) are shown as nanocones with p-type doping. In FIG. 3, the nanostructures (30) are truncated cones which merge at their bases.

In an embodiment, an intermediate layer of semiconducting material of the same type as the first semiconducting material of the primary array nanostructures is interposed between the bottom contact layer and the bases of these nanostructures. As shown in FIGS. 1-4, the layer (20) of the first semiconducting material attached to the nanostructures (30) may be planar and may be continuous or discontinuous. FIG. 1 shows the layer (20) as a continuous p+ layer (degenerate doping). FIG. 4 shows layer (20) as a discontinuous p+ layer. This intermediate layer can enable use of inexpensive and/or flexible supports, potentially reducing fabrication costs. However, this intermediate layer is not required and in some embodiments the nanostructures can be directly fabricated on the bottom contact layer. As referred to herein, the bottom of the photoactive layer is the side closest to the intermediate layer (if present) or closest to the contact layer on which the nanostructure arrays are fabricated. However, in use the photoactive layer may be oriented as desired, so the top of the layer as referred to herein may no longer be the top of the device.

In an aspect of the invention, the second semiconducting material (40) does not form a matrix embedding the first semiconducting material, but rather forms a relatively thin coating, shell, or layer over the nanostructures of the primary array. As shown in FIGS. 1-4, in some embodiments the layer of the second semiconducting materials may be attached to the first semiconducting material. The layer formed by the second semiconducting material (40) may be a partial layer which only covers one end of the elongated nanostructures (30) of the primary array. As shown in FIGS. 3 and 4, a layer of the second semiconducting material may be attached to the top of each nanostructure of the primary array. The layer (40) may also completely cover the exposed portions of the elongated nanostructures (30) of the primary array and the portion of the underlying semiconductor layer (20) which is not covered by the nanostructures (as shown in FIGS. 1 and 2). In FIG. 2, the second type of semiconducting material contacts the sides and the top of the p-type nanostructures and the top of the p-type semiconducting layer between the bases of the p-type nanostructures. In FIG. 1, coating (40) is shown as n-type.

In an embodiment, the photoactive layer also contains a third electrically insulating and optically transparent material. This insulating material can reduce surface recombination during device operation through passivation of semiconductor surfaces. This third material can enable the photoactive layer to have a planar top surface by filling the space not occupied by either the first or the second semiconducting material. In this embodiment, the insulating material thus serves as a matrix for the coated nanostructures. FIGS. 2-4 illustrate three different cell configurations including an electrically insulating transparent material (60). Although the insulating material looks discontinuous in these two-dimensional views, the insulating material is generally interconnected in three dimensions.

The invention provides several different photovoltaic cell configurations, some of which are shown in FIGS. 1-4. FIGS. 1a and 1b illustrate a cell configuration in which a planar contact electrode (10) is in electrical contact with the planar layer (20) of the first semiconducting material and a conformal transparent conducting coating (50) is in electrical contact with the second semiconducting material (40). In an embodiment, the nanostructures of the structure in FIG. 1 a have dimensions as follows. The primary array (30) may be approximately 400 nm high and separated by 350 nm, and the second semiconducting material may have an n-layer having a minimum thickness of 75 nm which is in contact with and covers the exposed surface of the nanocones (30) and the exposed portions of the layer (20). The conformal transparent conducting coating is shown as providing antireflection and contact functions.

More generally, the structure dimensions of the first and second type of semiconducting material can be selected to obtain the desired photovoltaic properties. The light trapping and optical properties depend upon the nanostructure height, the nanostructure density, nanostructure diameter and shape, and their optical constants. Surface roughness and aspect-ratios can also be used to describe a particular dependence.

FIGS. 2a, 3 and 4 illustrate cell configurations in which the photoactive layer is sandwiched between two planar contact layers (10, 70). In these figures, the upper conducting contact layer (70) is shown as providing antireflection, mechanical protection, and contact functions. The planar layer (20) of the first semiconducting material is in electrical contact with the first contact layer (10) and the second semiconducting material (40) is in electrical contact with the second contact layer (70). Use of an electrically insulating material (60) allows point contacts to be made between the upper planar contact layer (70) and the second semiconducting material (40), as shown. In the device shown in FIG. 3, the top layer of second semiconducting material may be approximately 20 nm. Point contacts can also be made between the lower planar contact layer (10) and a discontinuous layer (20) of the first semiconducting material as illustrated in FIG. 4. Point contacts are known to improve device efficiency. In this configuration, the insulator material passivates not only the sides of the cones, but also part of the backside electric contact. Alloying or structuring the substrate such that a point contact is obtained will reduce recombination at the back contact.

In the embodiments illustrated in FIGS. 1b and 2b, the top surface of the cell is not planarized, resulting in a non-planar conformal top electrical contact layer. Such a rough surface layer may allow for better trapping and absorption of light. Formation of insulating material and top conductor layers similarly to those shown in FIG. 2b allows similar configurations to be produced for the cells shown in FIGS. 3 and 4. In an embodiment, the elongated nanostructures of the secondary array are generally conical at the top, which can allow control of the roughness of the top contact layer when the top contact layer is conformally coated on the layers below.

The semiconducting materials in the photovoltaic device may be crystalline, amorphous or a combination thereof. Crystalline semiconducting materials include single crystal materials, nanocrystalline materials, and polycrystalline materials. In an embodiment, the semiconducting materials in the photovoltaic device contain both amorphous and crystalline silicon phases. In this embodiment, a higher optical absorption rate and a higher quantum conversion efficiency can be obtained due to the difference in band-gap width and due to the fact that amorphous silicon possesses a direct band gap.

However, it is expected that nanostructures based on a mostly single crystalline phase will show superior device performance. In another embodiment, the nanostructures are mostly crystalline. In an embodiment, the crystal quality of the nanostructures is improved by rapid thermal annealing after growth of the nanostructures and prior to deposition of further layers or oxidation.

In an embodiment, the nanostructures have high carrier diffusion lengths, low recombination velocities and band edges engineered to reduce contact recombination. Band-gap variations might also occur due to temperature changes and (internal) stresses. Band edge engineering includes direct control of the energy gap through the dimensions of the nanostructure. Note that when the nanostructure is a cone it is graded in diameter. Thus the upper end becomes in effect a quantum well of diminishing dimensions. It therefore exhibits an increased energy gap near the top end. Depending on surface strains and other effects, this can produce a minority carrier mirror that can prevent recombination at the top contact and aid in minority carrier collection. Quantum size effects can also serve to enhance optical absorption as in other quantum nanostructures

In an embodiment, the invention provides a photovoltaic cell comprising:
a. a first and a second electrical contact layer, at least one of the first and second contact layer being transparent; and
b. a nanostructured thin film comprising a secondary array of elongated nanostructures comprising a first and a second type of semiconducting material; and
   an intermediate layer of the first type of semiconducting material in contact with the first contact layer, wherein
   the nanostructures of the secondary array comprise a primary elongated nanostructure array comprising the first type of semiconducting material, the primary array being at least partially coated by a layer of the second type of semiconducting material, the first semiconducting material of the primary array of nanostructures contacts the intermediate layer, but not the first contact layer or the second contact layer, the second semiconducting material contacts the second contact layer, but not the first contact layer, the maximum width of each nanostructure of the secondary array is between about 2 nanometers and about 1 micrometer, the nanostructures of the secondary array are aligned so that their longitudinal axes are generally normal to the surface of the first contact layer and the first type of semiconducting material has a room temperature band gap less than or equal to 3 eV.

In another embodiment, the invention provides a photovoltaic cell comprising:
a. a first and a second electrical contact layer, at least one of the first and second contact layer being transparent; and
b. a nanostructured thin film comprising
   a secondary array of elongated nanostructures comprising a first and a second type of semiconducting material; and
   a layer of a transparent insulating material,
      wherein the nanostructures of the secondary array comprise a primary elongated nanostructure array comprising the first type of semiconducting material, the primary array being at least partially coated by a layer of the second type of semiconducting material, the first semiconducting material of the primary array of nanostructures contacts at least a portion of the first contact layer, but does not contact the second contact layer, the second semiconducting material contacts a portion of the second contact layer, but does not contact the first contact layer, the layer of transparent insulating material is attached to the portions of the nanostructures of the secondary array which are not in contact with either the first or second contact layer and the portions of the second contact layer which are not in contact with the second layer of semiconducting material, the maximum width of each nanostructure of the secondary array is between about 2 nanometers and about 1 micrometer, and the nanostructures of the secondary array are aligned so that their longitudinal axes are generally normal to the surface of the first contact layer.

The invention also provides methods for making the photoactive layers and photovoltaic and photosensing devices of the invention. One key step in the method for making the photoactive layer is preparation of the aligned nanostructures. In an embodiment, a first array of aligned nanostructures is formed. In an embodiment, the first array of nanostructures comprises the first semiconducting material and serves as the primary array. In another embodiment, additional material is deposited on the nanostructures of the first array to form the primary array. A second semiconducting material may then deposited be on the primary array to form a secondary array of coated nanostructures. Additional layers of semiconducting materials may be deposited to form more complicated structures such as multijunction cells.

In one embodiment of the invention, the aligned nanostructures are prepared by a process involving vapor-liquid-solid growth (VLS) from metal droplets formed on a semiconducting layer. For example, the process described in U.S. Pat. No. 5,858,862 can be used if the semiconducting layer is single crystal silicon. The process in U.S. Pat. No. 5,858,862 involves formation of gold droplets on the surface. A ion-assisted VLS-type process involving use of droplets of metals with lower melting temperatures which is compatible with polycrystalline silicon substrates is described in more detail below and in U.S. Provisional application 60/811,033 filed Jun. 5, 2006 and in concurrently filed U.S. and PCT applications entitled “Method for Growing Arrays of Aligned Nanostructures on Surfaces”, Attorney Docket Nos 83-06 and 83-06 WO, all hereby incorporated by reference. Reactive ion etching (RIE) can also be used to make the aligned nanostructures. Since RIE is a subtractive process, it may involve greater quantities of silicon material, and thus higher silicon material costs. Other non-VLS growth methods for self-organized small structure arrays include VSS solid state epitaxial growth, GLAD, laser irradiation, and ion etching.

In one aspect the invention provides a method for making a nanostructured solar cell comprising the steps of:
a. providing an electrically conducting substrate
b. depositing a continuous intermediate layer of a first type of semiconducting material on the upper surface of the conducting substrate;
c. forming a primary array of generally aligned elongated nanostructures on the upper surface of the intermediate layer, the nanostructures of the primary array comprising the first type of semiconductor;
d. forming a layer of a second type of semiconducting material which at least partially coats the nanostructures of the primary array; thereby forming a secondary array
e. depositing a layer of transparent conducting material such that the layer of conducting material is at least partially in contact with the layer of the second type of semiconductor but not is in contact with the nanostructures of the primary array or the intermediate layer.

### BRIEF DESCRIPTION OF THE FIGURES

FIGS. 1a and 1b: Photovoltaic cells employing an aligned array of elongate semiconducting nanostructures in which the top contact is made through a conformal coating of a transparent conductor.

FIGS. 2a and 2b: Photovoltaic cells employing an aligned array of elongate semiconducting nanostructures and an insulating material, with point contacts being made to the n-layer.

FIG. 3: Another photovoltaic cell configuration employing an aligned array of elongate semiconducting nanostructures and an insulating material, with point contacts being made to the n-layer.

FIG. 4: A photovoltaic cell employing an aligned array of elongate semiconducting nanostructures and an insulating material, with point contacts being made to both the n-layer and the p-layer.

### DETAILED DESCRIPTION OF THE INVENTION

The photovoltaic and photosensing devices of the invention include a photoactive layer which contains a nanostructured semiconducting thin film. As used herein, a nanostructured thin film contains structures having a maximum width or diameter between about 1 nm and about 1 micron.

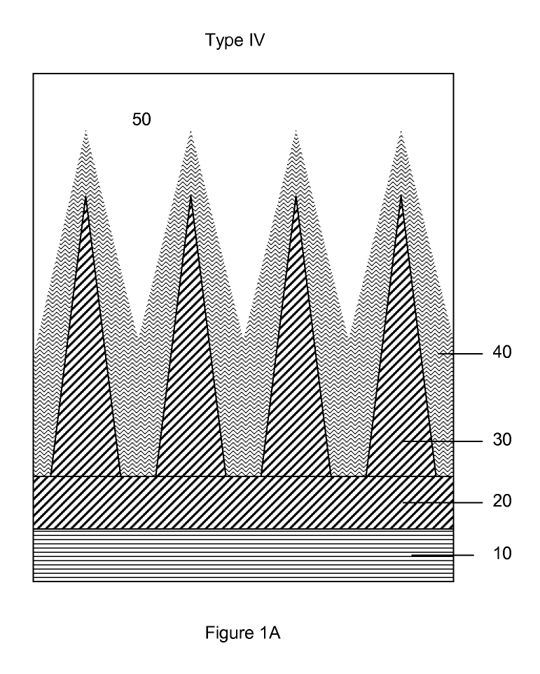

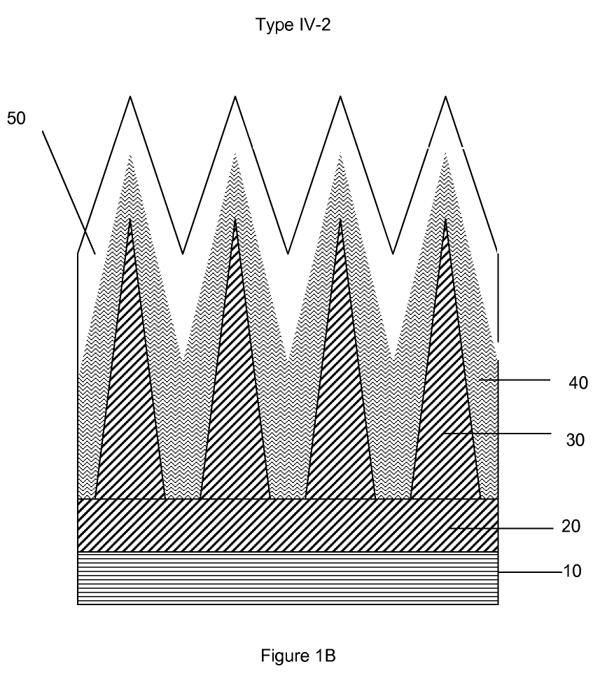

In an embodiment, a photoactive layer contains an active material which is capable of absorbing at least some wavelengths of light and generating an electron-hole pair. In an aspect of the invention, the nanostructured thin film contains one or more junctions between different types of semiconductor materials. In an aspect of the invention, the photoactive layer comprises a secondary nanostructure array which comprises both a first and a second type of semiconductor material. The secondary array may also comprise two or more types of semiconducting material. In an embodiment, the nanostructures of the secondary array consist essentially of the first and second types of semiconducting material, as illustrated in FIGS. 1-4. The secondary array comprises a primary array of elongated nanostructures, the primary array comprising at least one of the types of semiconducting material.

The nanostructures of the primary array are optionally attached to a planar layer. In different embodiments, the thickness of the nanostructured thin film is between 0.1 microns and 100 microns.

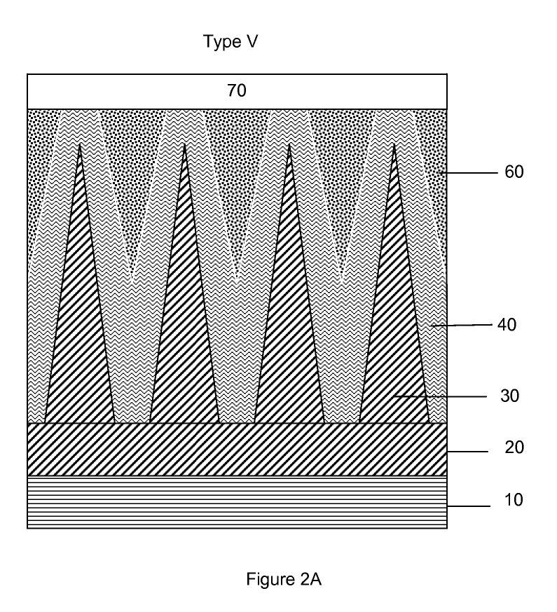

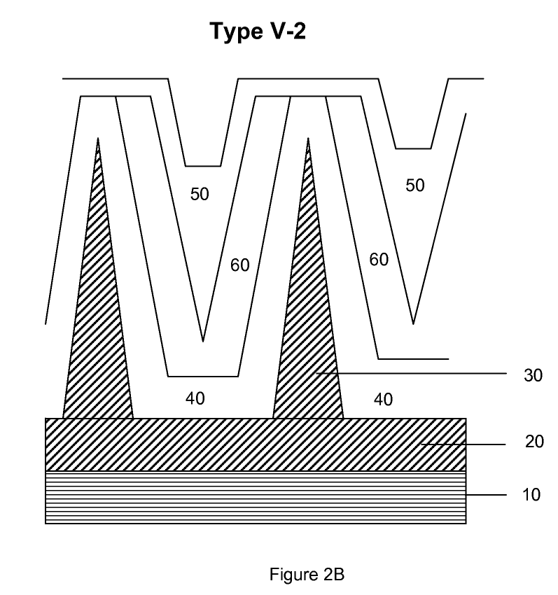

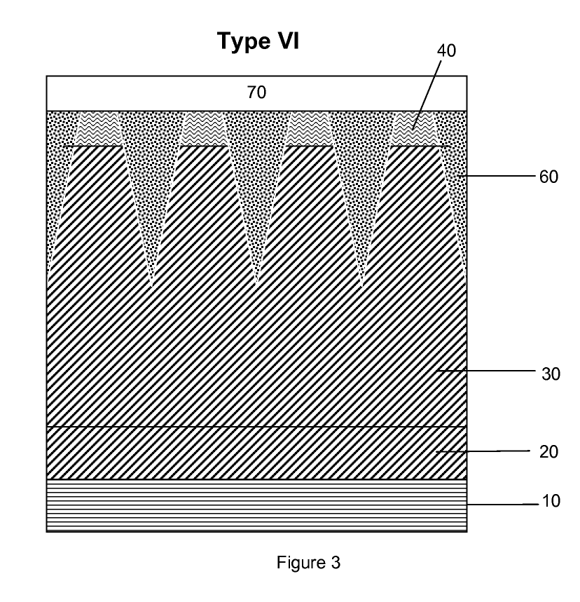

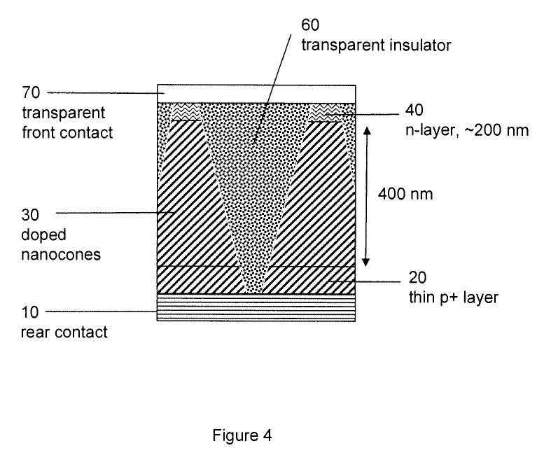

As used herein, elongated nanostructures include, but are not limited to, nanowires, nanorods, nanowhiskers, nanocones, nanopyramids, and truncated and/or conjoined nanocones and nanopyramids. As used herein, truncated nanocones and nanopyramids are sections of nanocones or nanopyramids. For example, the top of a nanocone may be removed during processing leaving behind a conical section as illustrated in FIGS. 2 and 4. Conjoined nanocones or nanopyramids merge together at their bases, as illustrated in FIG. 3. The characteristic width of conjoined nanostructures is determined above the conjoined portion. In an embodiment, the mean distance between the nanostructures is not much larger than the incident light wavelength to reduce reflections from in between the structures. In another embodiment, the distance between the nanostructures is selected to increase the number of reflections between the structures. In an embodiment, the elongated nanostructures of the primary array are nanowires or nanocones. In an embodiment, the elongated nanostructures of the secondary array are nanowires, nanocones, or conjoined nanocones.

The elongated nanostructures are of nanometer dimensions in their width or diameter, having a maximum width or diameter between about 1 nm and about 1 micron. In other embodiments, the width or diameter of the secondary array nanostructures of the invention is between about 2 nm and about 1 micron, about 10 nm and about 400 nm or between about 50 nm and about 200 nm. Nanowires, nanorods, and nanowhiskers, are also sometimes referred to as “one-dimensional” nanostructures. The nanostructures are provided in the form of an array. The density of the array may be in the range between 0.1 and 10,000 per micron squared, between 4 and 100 per micron squared, between 1 and 5 per micron squared, and between 10 and 50 per micron squared. The nanostructures of the array are generally aligned. Perfect alignment is not required. In an embodiment, the variation in nanostructure alignment is between +/−4 and +/−6 degrees. In other embodiments, the variation in nanostructure alignment is from +/−5 to +/−40 degrees. As referred to herein, the nanostructures are generally aligned normal to the surface of the first contact layer if they are aligned within these ranges.

In an embodiment, the nanostructures of the primary array comprise the first type of semiconducting material. In an embodiment, the nanostructures of the primary array comprise a core of a non-semiconducting material at least partially surrounded by a shell comprising the first type of semiconducting material. In this embodiment, the cores may be an electrically insulating material. For example, the cores may be of an oxide material, such as a silicon oxide. In another embodiment, the nanostructures of the primary array comprise a core of a semiconducting material coated by an insulating material, this cores being at least partially surrounded by a shell comprising the first type of semiconducting material. For example, the cores may be of silicon coated with an oxide layer. In another embodiment, the nanostructures of the primary array consist essentially of the first type of semiconducting material.

In another aspect of the invention, the nanostructures of the primary array may comprise an intrinsic semiconductor in addition to a doped first type of semiconducting material. In an embodiment, the nanostructures of the primary array may comprise a doped semiconducting material at least partially surrounded by a shell of an intrinsic semiconducting material. When the nanostructures of the primary array comprise a core of an insulating material, the shell of semiconducting material may comprise an inner shell of doped semiconducting material surrounded by an outer shell of an intrinsic semiconducting material.

In an embodiment, the second type of semiconducting material is the form of a layer which at least partially coats the external surface of the primary array nanostructures of nanostructures formed during the fabrication process. The first array comprises the first semiconducting material. For example, in FIG. 2a, the layer of the second semiconducting material wholly coats the external surface of the nanostructures of the first semiconducting material. In FIGS. 3 and 4, the second type of semiconductor is present only at the tops of the nanostructures. In an embodiment, the layer of the second type of semiconducting material (the n-layer in FIG. 1) will have a minimum thickness of 10 nm. The coating forms a one or more junctions between different types of semiconductor materials. For example, if the exterior of the primary array nanostructures is a p-type semiconductor, the n-type coating forms a p-n junction. As another example, if the exterior coating of the primary array nanostructures is an intrinsic semiconductor then the junction is formed between the intrinsic semiconductor and the p-type or n-type coating. In an embodiment, only a portion of the layer of the second semiconducting material contacts the second contact layer. For example, in FIG. 3 only the top of the layer of the second semiconducting material contacts the second contact layer; the sides are contacted by insulating material.

In an embodiment, the primary array of nanostructures is attached to a semiconductor layer which is intermediate between the bottom electrical contact layer and the bases of the primary nanostructures. In an embodiment, the intermediate layer is also of the first type of semiconductor. In an embodiment, the doping type of the intermediate layer and at least a portion of the nanostructure is the same. However, the doping level can be different in the primary array nanostructures and the layer. In an embodiment, the doping level is not lower in the intermediate underlayer. In an embodiment, the doping level is higher in the underlayer (eventually reaching a degenerate doping level (p+ or n+). The intermediate layer may be planar or non-planar. In other aspects of the invention, this layer may be smooth or rough. The thickness of the layer to which the primary nanostructures are attached can be arbitrarily thin. In an embodiment, the thickness of the layer is a few hundred of nanometers thick. In an embodiment the intermediate layer is continuous and the second contact layer is transparent. In another embodiment, the intermediate layer is discontinuous.

In other embodiments, no intermediate semiconductor layer is required between the primary nanostructures and the electrical contact layer.

The total amount of semiconductor material in the photoactive layer can be compared to that of a dense semiconductor layer of equivalent thickness, of equivalent mass or volume, or of equivalent optical thickness. In different embodiments, the density of the semiconductor layer (volume fraction) is between 20% and about 60% or about 50%.

Suitable semiconductor materials for the photoactive layer include, but are not limited to a combination of n-type and p-type silicon. In an embodiment, the elongated nanostructures of the secondary array are made of one of p-type or n-type silicon with a relatively thin coating of the other of p-type or n-type silicon. In another embodiment, the elongated nanostructures of the secondary array are of p-type or n-type silicon at least partially surrounding a core of non-semiconducting material. In embodiments where the device fabrication process involves a planarization step which removes part of the layer of the second type of semiconducting material, the thickness of the coating is sufficiently thick to compensate for any variations in height of the nanostructures. The thickness of the layer of the second type of semiconducting material is determined by the process used. In yet another embodiment, an intrinsic layer may be formed between the nanostructures and the layer having the opposite doping. For example, p-type nanostructures may be in contact with an intrinsic layer which in turn is in contact with an n-layer. In this case, the nanostructured thin film may be viewed as including three types of semiconducting material.

Other combinations of semiconducting materials are also suitable for use with the invention. These semiconducting materials may also be doped to obtain the desired conductivity type. For example, GaAs nanowire formation by a VLS process is known in the art. Other embodiments could include CdTe, CdSe, or I-III-VI combinations such as copper indium selenide (CuInSe₂ or CIS), and copper indium gallium selenide (CIGS) or copper gallium selenide (CGS). Suitable combinations of semiconducting materials for solar cells are known to those skilled in the art. In an embodiment, neither the first or the second semiconducting material is a polymer. In different embodiments, the band gap of the first semiconducting material is less than about 3 eV or less than about 2.5 eV at room temperature (between about 20-25° C.). In another embodiment, the first semiconducting material is not a transparent conducting oxide such as tin oxide, indium tin oxide or zinc oxide.

In an embodiment, the photoactive layer also contains a transparent electrically insulating material. Suitable materials for this electrically insulating material include wide band-gap oxides including, but not limited to, SiO₂. This material may be amorphous. In another embodiment, a layer of the electrically insulating material may be formed over the surfaces of the nanostructured thin film. For example, for the device shown in FIG. 2, the layer of the electrically insulating material is formed over the n-layer surface. For a silicon nanostructured thin film, the layer can be formed by oxidation of the silicon surface. Suitable oxidation methods include, but are not limited to, ozone oxidation. Ozone oxidation produces a very high quality self-limiting oxide a few nanometers thick. Silicon oxidation can be performed at relatively low temperatures (250° C.) in the presence of 172 nm light from an xenon excimer lamp (Boyd, I. W. et al., 1997, Mat. Res. Soc. Symp. Proc. Vol 470, 343-354). Surface passivation can also be accomplished with surfactant treatment. The remainder of the filler material may be a transparent dielectric, or a transparent conductive material. The nature of the intercolumnar filler material can enhance light trapping in the cones as well as passivating the device electrically and provide mechanical protection (stabilization) of the nanostructures.

In an embodiment, the top of the photoactive layer is planar. In embodiments where an electrically insulating insulating material is used to fill in the gaps between the coating layer of the second semiconducting material and the top contact layer, the top of the insulating material and the top of the coating material together form a planar surface (for example see FIGS. 2a and 3).

In an aspect of the invention, the photoactive layer is sandwiched between two electrical contact layers. Each of these layers comprises an electrically conductive material. The two layers function as electrodes, allowing electrical contact to be made to the two types of semiconducting material. Only one contact layer is in direct electrical contact with each kind of semiconducting material. For solar cell applications, at least one of the two layers is transparent to the desired wavelengths of radiation. In an embodiment, at least one of the layers is optically transparent. The top electrical contact in the cell configurations shown in FIGS. 1-4 can be made of thin layer of a transparent conducting oxide such as tin oxide, indium tin oxide, or zinc oxide. This layer may be a conformal layer and need not be planar, as illustrated in FIGS. 1b and 2b. The lower electrical contact need not be transparent. In an embodiment, the lower electrical contact is a metal substrate. In another embodiment, the lower electrical contact is electrically conductive material mechanically supported by a non-conductive substrate, such as a polymer or a dielectric material.

In one aspect, the invention provides a photovoltaic cell comprising:
a. an electrically conducting substrate having an upper and a lower surface;
b. a nanostructured semiconducting thin film comprising
   a first portion of a first type of semiconducting material, the first portion comprising
   a continuous layer of the first type of material attached to the upper surface of the conducting substrate and
   an array of elongated nanostructures of the first type of material, wherein each nanostructure of the first type of material is aligned so that its longitudinal axis is substantially normal to the surface of the substrate, the base of array being attached to the upper surface of the layer of the first type of material; and
   a second portion of a second type of semiconducting material, the second portion comprising a discontinuous layer of the second type of material, the bottom of each portion of the layer of the second type of material being attached to the top surface or top part of one of the nanostructures of the first type of material;
c. a transparent electrically insulating material in contact with the nanostructures of the first type of material and the layer of the second type of material;
d. a transparent conducting layer attached to the top of the insulating material and the n-type layer,
wherein the maximum width of each nanostructure is between about 10 nm and about one micrometer.

In another aspect, the invention provides photovoltaic cell comprising:
a. an electrically conducting substrate having an upper and a lower surface;
b. a nanostructured semiconducting thin film comprising
   a first portion of a first type of semiconducting material, the first portion comprising
   a discontinuous layer of the first type of material attached to the upper surface of the electrically conducting substrate and
   an array of elongated nanostructures of the first type of material, wherein the base of each nanostructure of the first type of material is attached to the upper surface of the layer of the first type of material and each nanostructure is aligned so that its longitudinal axis is substantially normal to the surface of the substrate;
   a second portion of a second semiconducting material, the second portion comprising a discontinuous layer of the second type of material, the bottom of each portion of the layer of the second type of material being in contact with the top of one of the nanostructures of the first type of material;
c. a transparent electrically insulating material in contact with the first and second portions of the film and the electrically conducting substrate; and
d. a transparent conducting layer attached to the top of the insulating material and the layer of the second type of material,
   wherein the maximum width of each nanostructure is between about 10 nm and about one micrometer.

In another aspect, the invention provides a photovoltaic cell comprising:
a. a electrically conducting substrate having an upper and a lower surface;
b. a nanostructured semiconducting thin film comprising
   a first portion of a first type of semiconducting material, the first portion comprising
   a continuous layer of the first type of material attached to the upper surface of the conducting substrate and an array of elongated nanostructures comprising the first type of material, wherein the base of each nanostructure of the first type of material is attached to the upper surface of the layer of the first type of material and each nanostructure is aligned so that its longitudinal axis is substantially normal to the surface of the substrate; and
   a second portion of a second type of semiconducting material, the second portion comprising a continuous layer of the second type of material in contact with the first portion of the film;
c. a transparent electrically insulating material in contact with the layer of the second type of material;
d. a transparent conducting layer attached to the top of the insulating material and the layer of the second type of material,
   wherein the maximum width of each nanostructure is between about 10 nanometers and about 1 micrometer.

Scheme 1 presents a flow chart illustrating a list of processing steps which can be used to make cell types IV (FIG. 1a), V (FIG. 2a) and VI (FIG. 3) from a combination of n-type and p-type silicon. The scheme presents the nanostructures as being of p-type, but in other embodiments nanostructures may also be n-type, as described above. One of ordinary skill in the art could modify scheme 1 appropriately to be suitable for n-type nanostructures. Similarly, a similar scheme would be applicable for other combinations of semiconductor materials, although the temperatures and materials used would change. In addition, although the nanostructures are shown as cones in FIGS. 1-3, the process can be adjusted to produce other shapes.

The flow chart assumes that the bottom electrical contact (10) is a metallic substrate. The flow chart also assumes that the semiconducting cones are grown by a VLS-type mechanism. The bases of cones grown by this mechanism typically do not contact each other. Therefore, to obtain a structure where the bases are in contact with each other an additional deposition step (and doping step) can be used to thicken the cones. Such a deposition step can also be used to obtain a smaller amount of thickening. In another embodiment, a VLS-type process is used to produce a first array of non-semiconducting nanostructures. Deposition of a semiconducting material on these non-semiconducting nanostructures (optionally after VLS promoter removal) can give semiconductor-containing nanostructures (the primary array) which can then be processed similarly to Scheme 1.

To produce the structures shown in FIGS. 1-4, the cones are p-type silicon. The coating deposited on the cones is either amorphous silicon (a-Si) or polycrystalline silicon (pc-SiC).

To produce the structures shown in FIGS. 1-2, n-type dopant material is applied and thermally diffused into the a-Si or pc-Si layer. The n-dopant may be allowed to diffuse past the a/pc-material, to diffuse just to the interface of the a/pc material and the underlying nanostructure, or to diffuse only that so far that a small intrinsic region between p and -type material occurs (a region with negligible doping). This portion of the process can be viewed as taking the first array of aligned elongated nanostructures, in which the nanostructures are p-type silicon (primary array), and converting it to a second type array of aligned elongated nanostructures, in which the nanostructures are p-type silicon covered with a layer of n-type silicon (secondary array).

To produce the structure shown in FIG. 3, the cones are first thickened so their bases contact each other. This portion of the process can be viewed as taking the first array of aligned elongated nanostructures, in which the nanostructures are p-type silicon, and converting it to a second type array of aligned elongated p-type silicon nanostructures, in which the nanostructures are p-type silicon covered with a layer of a-Si or pc-Si p-type silicon (primary array). The p-type doping of the additional layer could be done during deposition (e.g. by sputtering of a p-type target) or by thermal diffusion. Then, after the deposition of the insulating material and planarization, additional dopant is applied to produce a top n-layer. Note that if the bases of the nanostructures do not completely cover the underlying p-type silicon layer, a layer of insulating material is formed on the underlying layer as well. In another embodiment, this top n-layer is doped using low-energy ion implantation. A third type array of elongated nanostructures is thus generated, the nanostructures of the third array being of p-type silicon with a top layer of n-type silicon (secondary array). The n-type dopant layer may be thicker than, equal to, or thinner than the a-Si or pc-Si coating thickness.

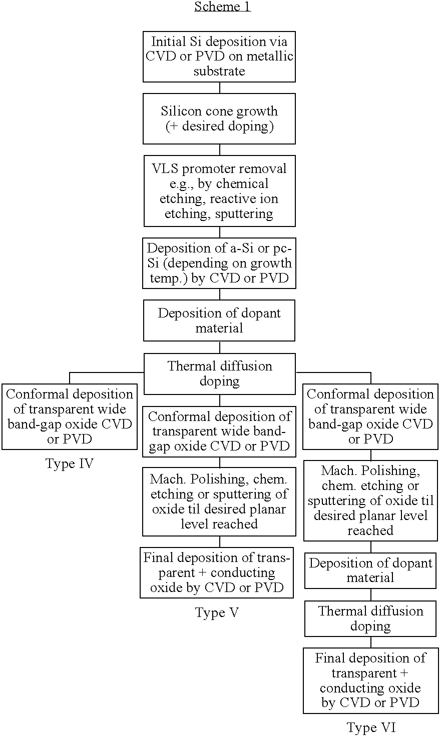

The structure shown in FIG. 4 can be produced by a method similar to that used to produce the structure of FIG. 3 The thin silicon intermediate layer is initially continuous, but portions of the intermediate layer in between the cone-bases is removed after growth of the cones and prior to deposition of the insulating material. If the nanostructures are sufficiently broad after synthesis the a/pc-Si deposition and doping steps are not required. Possible methods for removal of this portion of the silicon layer include sputtering in an inert atmosphere and reactive ion etching. Although removal of this portion of the silicon layer may remove some material from the cones as well, the amount of material in the layer is expected to be much less than the amount in the cones. The subsequent deposition of the insulator material then passivates not only the sides of the cones, but also part of the backside electric contact. If the electric contact is a p-type dopant material (e.g. aluminum), contamination during removal of the thin Si layer may not be a concern, since the cones already comprise p-doped material. The configuration of FIG. 4 is symmetric, which allows alternate process schemes which can lead to a reduction of processing and materials costs. For instance, the nanocones can be grown on a silicon layer deposited on a transparent conductor (E.g. ITO) and the cell finished with a thermally evaporated metal thin film.

Planarization may be achieved by machine polishing, chemical etching, sputtering in an inert atmosphere and reactive ion etching. Reactive ion etching may be done at normal or grazing incidence.

In an embodiment, the invention provides a method for making a nanostructured photovoltaic cell comprising the steps of:
a. providing an electrically conducting substrate;
b. depositing a continuous layer of a semiconducting material of a first type on the upper surface of the conducting substrate, the semiconducting material being one of p-type or n-type;
c. forming a first array of aligned elongated nanostructures on the upper surface of the layer of the first type of semiconducting material, the nanostructures of the first array comprising the first type of semiconducting material;
d. depositing a amorphous or polycrystalline layer of an intrinsic semiconducting material, the intrinsic semiconducting material layer covering the elongated nanostructures of the first array;
e. depositing a layer of dopant material, the layer of dopant material covering the layer of instrinsic semiconducting material and the dopant material being selected to be n-type when the first type of semiconducting material is p-type and p-type when the first type of semiconducting material is n-type;
f. thermally diffusing the dopant material into the intrinsic semiconducting layer, thereby forming a second array of aligned elongated nanostructures, the nanostructures of the second array being of the first type of semiconducting material covered by a layer of a second type of semiconducting material, the second type of semiconducting material being the other of p-type or n-type; and
g. depositing a layer of transparent conducting material, the layer of transparent conducting material covering the layer of the second type of semiconducting material of the second array.

In an embodiment, the array of aligned semiconductor nanostructures is produced via a modified ion-assisted VLS-type method. In an embodiment, this method comprises the steps of:
a) providing a substrate in a vacuum chamber;
b) forming a layer of mediating material on a surface of the substrate, wherein the mediating material, when molten, forms droplets on the substrate surface;
c) heating said substrate and mediating material to a temperature sufficient to melt the mediating material in a vacuum atmosphere, the atmosphere comprising a component which is selected from the group consisting of noble gases, nitrogen and combinations thereof; and
d) synthesizing aligned elongated nanostructures of a selected chemical composition at the mediating material droplets, the nanostructures extending up from the substrate surface and being located generally under the mediating material droplets by
   i) providing a source of each chemical element of the selected composition;
   ii) generating a plasma in the vacuum chamber, thereby forming plasma species including positive ions; and
   iii) inducing a negative electric potential on the substrate relative to the plasma, thereby directing positive ions towards the substrate surface.

In another embodiment, the modified ion-assisted VLS-type method comprises the steps of:
a. providing a substrate in a vacuum chamber;
b. forming a layer of mediating material on the substrate, wherein the mediating material, when molten, forms droplets on the substrate surface;
c. heating said substrate and the mediating material to a temperature sufficient to melt the mediating material and form mediating material droplets on the substrate surface;
d. synthesizing aligned elongated nanostructures of a selected chemical composition at the mediating material droplets, the nanostructures extending up from the substrate surface and being located generally under the mediating material droplets by
   i) providing a source of each chemical element of the selected composition
   ii) directing an ion beam at said substrate surface, said beam having ion energies in the range of 10 eV to 5 keV.

The nanostructures formed via ion-assisted VLS-type methods may be made of a variety of materials, including, but not limited to, semiconductors, oxides, nitrides, carbides and combinations thereof. Exemplary oxides, carbides, and nitrides include, but are not limited to, SiO₂, SiC and Si₃N₄

In this method, at least one surface of the substrate is suitable for vapor-liquid-solid (VLS)-type growth of the selected material or chemical composition. In an embodiment, the surface of the substrate may be formed by a coating applied to an underlying support. In other embodiments, one or more underlying layers may be formed on the underlying support.

For growth of silicon-containing elongated nanostructures, the surface may be silicon or silicon with a native oxide layer. Either type of surface will generally allow mediating material droplets of suitable size to be produced during the melting step. However, the interaction between the substrate and the mediating material is critical, so some choices of mediating material may require special choices of substrate surface. A silicon surface may be obtained by using a silicon wafer as a substrate, or by depositing a film of silicon onto another substrate material. Suitable substrate surfaces for carbon-containing nanostructures include Si or native Si oxide on silicon as well as various carbon coatings.

In one aspect of the invention, an “intermediate layer” is deposited onto an underlying support. For use in the solar cells of the invention, the intermediate layer is generally of the same type of semiconducting material as the first semiconducting material, although the doping level may be different. In an embodiment, the intermediate layer is composed of silicon, and no special treatment of the film is needed to assure a particular crystal structure or orientation. Typically the intermediate layer is a few hundreds of nanometers thick. The film may be amorphous, nanocrystalline or polycrystalline depending on the deposition conditions. The intermediate layer provides a well-controlled surface for the critical mediating material deposition step to follow, and may be selected to promote the formation of nanodroplets of the mediating material, as well as to control nucleation of the selected material upon the intermediate layer during the earliest stages of growth. It also provides a barrier which prevents contamination of the nanostructure growth process by the support material and damage to the support by the nanostructure growth process. When the exposed intermediate layer is not being used as a feedstock for nanostructure growth, the net rate of growth vs. etching for the intermediate layer is nearly zero, so a very thin layer is adequate for most functions. The underlying support material (as well as any layers deposited above the support) must be able to survive temperatures on the order of the melting temperature of the mediating material. In an embodiment, the underlying support material can withstand temperatures of roughly 120 to 350 degrees Celsius without melting or giving off significant vapor (i.e. the material must be vacuum-compatible at the process temperature). Suitable underlying support materials include metals, polymers, glasses and ceramics. In an embodiment, the support material is electrically conductive. In an embodiment, the underlying support is steel, the intermediate layer is silicon, and the intermediate layer can be directly deposited onto the support by magnetron sputtering in argon. In some cases, it may be desirable to deposit a thin (a few nanometers to tens of nanometers) interface or adhesion layer between the underlying support and the intermediate layer to improve bonding. For example, the use of a thin titanium or chromium layer is well known as a method of improving adhesion of thin gold films to glass. Additional intermediate layers to serve as diffusion barriers might be needed if prolonged exposure to high temperatures would be expected. For example, a variety of materials are used in the semiconductor industry to isolate copper from silicon in integrated circuits to avoid the formation of copper silicide. In an embodiment, the nanostructure formation process includes the step of depositing the intermediate layer on the support after the support is placed in the vacuum chamber. Methods for deposition of intermediate layer films such as silicon are well known to those skilled in the art, and include, but are not limited to magnetron sputter deposition, evaporation, chemical vapor deposition, and the like.

The mediating material facilitates the VLS-like process. In an embodiment, the mediating material is selected so that it does not form stable reactant-rich phases at reactant concentrations experienced in the growth environment, and has low solubility in the nanowire or nanotube material. Therefore, the mediating material is not substantially consumed during growth of the nanotubes or nanowires. However, if the mediating material is to be used to dope the nanostructure, a limited amount of solubility is desirable. Typically, the mediating material is a metal. In an embodiment, suitable metals for use as mediating materials include, but are not limited to, indium, tin, gallium, bismuth, aluminum, mercury, cadmium, lead, thallium gold, zinc, tellurium, lithium, sodium, potassium and combinations thereof. In an embodiment, the metal is selected from the group consisting of indium, tin, gallium, bismuth, aluminum and alloys thereof. In another embodiment, the metal is selected from the group consisting of indium, tin, gallium, bismuth, and alloys thereof. In an embodiment, the initial composition of the mediating material is pure indium. An indium containing mediating material may be used in combination with a silicon intermediate layer. During the synthesis process, the composition of the mediating material will typically change as it takes the reactants into solution. In an embodiment, the thickness of the film of mediating material is 10-30 nm. The film thickness determines the droplet size. In an embodiment, the size of the droplets is between 50 nm and about 200 nm. In an embodiment, for indium films approximately 20 nm thick, the initial droplet size is approximately 100 nm. After a droplet array has formed, it can continue to ripen, evolving into an array of larger, less numerous droplets. Ripening occurs most quickly during ion irradiation, but virtually halts when growth begins and the droplets lift off the surface. Controlled ripening allows deliberate reduction of the resulting nanostructure density, a useful feature for some applications. Methods for mediating material layer deposition include any suitable method known to those skilled in the art, including, but not limited to vacuum evaporation and sputter deposition. For thermal evaporation, the material must be heated to allow significant vapor pressure. In an embodiment, the vacuum environment provides a pressure low enough to prevent condensation of the evaporant into clusters or droplets before it reaches the sample.

In an embodiment, the mediating material is selected so that it provides the desired doping of the nanostructure. For example, use of indium as the mediating material can provide p-doping of silicon. The mediating material can also be selected to provide doping of semiconductor layers deposited on top of the nanostructures.

The substrate is heated in order to melt the metal mediating layer. The substrate may be heated by any method known to the art, including by a lamp, resistive heating, or from the plasma (ion or electron induced heating). In different embodiments, the substrate temperature is heated to a temperature less than 400° C., less than or equal to 350° C., or less than or equal to 250° C., between 150 and 250° C., or approximately 200° C.

In an embodiment, the substrate is heated in a vacuum atmosphere. In an embodiment, the total pressure in the vacuum chamber is between about 10 mTorr and about 40 mTorr or about 30 mTorr. In other embodiments, the pressure is from 10 mTorr to 200 mTorr, from 30 mTorr to 200 mTorr, or from 40 mTorr to 150 mTorr, or from 30 to 100 mTorr. Depending on the particular synthesis method, the atmosphere in the vacuum chamber may comprise one or more components selected from plasma forming components, feedstock components which provide sources of elements used to form the nanostructures, and etching components. Any of these components may be a gas mixture. For example, the etching component may be mixture of an etchant such as hydrogen with a relatively inert gas such as argon.

A source of each element of the selected nanostructure composition is provided in the reactant chamber. In an embodiment, sputtered atoms provide one or more elements of the nanostructure composition. Typically, the sputtered atoms are produced through interaction of a plasma with a solid target material. For example, the source of silicon can be silicon atoms produced by magnetron sputtering of a silicon target. The growth of compounds may be accomplished through the use of compound targets, or by the use of elemental targets in a suitably reactive plasma environment. The plasma can also be used to remove features and atoms on the substrate.

In another embodiment, a vapor phase precursor decomposes to form at least some of the desired elements of the nanostructure. For example, the source of silicon can be silane, a gaseous compound of silicon and hydrogen. Under stimulation from the electrical discharge near the substrate, silane can decompose at the liquid metal droplets, leaving silicon behind. The silicon tends to join the growing projections rather than remain in the liquid metal. In an embodiment, the silane is part of a gas mixture which comprises hydrogen and may further comprise other gases. In an embodiment, at least some of the silane comes from sources other than etching of the substrate or silicon features on the substrate. In an embodiment, the silane precursor can be obtained by passing hydrogen through a plasma column with a large exposed silicon surface area under ion bombardment. By controlling the rate of gas flow and the plasma intensity in the silane-generating column, the silane concentration can be controlled, and thus the ratio of growth to etching of the nanostructures. A gas phase environment for carbon nanostructures can be easily created by bubbling a carrier gas (e.g. Ar) through a liquid hydrocarbon (e.g. benzene) or through use of a hydrocarbon gas. Sources for carbon-containing materials include hydrocarbon gases such as methane. In addition, for formation of silicon carbide, a combination of silicon and carbon sources can be used.

In another embodiment, additional “doping” elements are introduced into the vacuum chamber so that they are incorporated into the nanostructure as it grows. The doping elements may be introduced by introduction of suitable gases or by any other method known to those skilled in the art. Doping can occur during initial synthesis of the nanostructures or during later deposition steps. For example, p-doping of silicon can be achieved by incorporating group III elements such as indium, gallium, boron or aluminum into the nanostructure, while n-doping can be achieved by incorporating group V elements such as phosphorus, or antimony. Doping of semiconductors is well known to those skilled in the art.

Without wishing to be bound by any particular belief, the aligned growth is believed to occur through an ion-assisted modified VLS mechanism. Growth of the nanostructures can occur through a VLS-type mechanism at the droplets or islands of mediating material. More than one nanostructure can be grown from a single droplet. In an embodiment, two to a few nanostructures are grown from each droplet. In an embodiment, addition of material to the sidewalls of the nanostructures during the synthesis process can also contribute to the overall growth of the nanostructures. For example, when sputtered atoms contribute to the nanostructure growth, some of the sputtered atoms may be deposited on the sidewalls and cause thickening of the nanostructure while other sputtered atoms are incorporated into the nanostructures through the mediating material.

Ion bombardment of the samples is believed to contribute both to growth and alignment of the structures. In fact, in an embodiment, ion bombardment from an ion gun can be the sole directing influence for aligned growth of the nanostructures. Ion bombardment can influence reactivity and adsorption rates at surfaces (as in ion-assisted CVD). For example, ion irradiation can provide the energy needed to promote reactions on the droplet surfaces (especially involving gas phase precursors), as well as within the droplets, that would not otherwise occur because of the low substrate temperature. Ion irradiation can also stimulate diffusion. In addition, any material removed from the substrate by sputtering can contribute to growth of the nanostructures through its incorporation into the structures. Ion irradiation can play a particularly significant role in the production of aligned arrays of widely-spaced nanostructures; that is, those for which the spacing between the nanostructures is too large to support the alignment mechanisms as mediated by “crowding” or van der Waals forces.

Ion irradiation can contribute to alignment through several mechanisms; the synthesis conditions will determine the operative mechanism(s). In an embodiment, ion irradiation can lead to etching of the nanostructures; selective etching of the nanostructures can assist in alignment of the structures. Without wishing to be bound by any particular theory, it is believed that nanostructure projections not aligned with the ion bombardment can be shaped by etching and sidewall growth until they are aligned; otherwise they etch away by a process similar to reactive ion etching. In an embodiment, the ions bombarding the sample are well aligned and have relatively high energies. In one embodiment, the ions extracted through the plasma sheath towards the substrate bombard the substrate surface at a near normal angle of incidence. For a hydrogen-containing plasma, these positive ions include hydrogen ions, which are very light. The liquid metal mediating droplets are believed to be largely unaffected by hydrogen bombardment, and therefore can shield nanostructures which have grown beneath them and are aligned with the bombardment. However, nanostructure projections that are not aligned with the ion bombardment tend to be shaped by etching and sidewall growth until they are aligned; otherwise they etch away by a process similar to reactive ion etching. If heavier ions such as argon are present in the plasma, these ions can also bombard the sample. In this case, the liquid metal droplets can be affected by the ion bombardment and the mediating material can gradually be sputtered away. This etching process can be particularly helpful for the removal of structures that have lost their mediating metal and have ceased to grow, or have, for any reason, collapsed onto the substrate. Gases other than hydrogen are known to the art for reactive ion etching of various materials (Anner, G. E., Planar Processing Primer (1990), Van Nostrand Reinhold, New York).

The alignment of the nanostructures can also be influenced by the bombardment of the exposed surfaces of the mediating material droplets. Without wishing to be bound by any particular theory, it is believed that bombardment of the mediating material droplets by ions and fast neutrals can stimulate mixing, suppress nucleation, influence the relative supersaturation of the concealed and exposed surfaces of the droplets, and/or transfer momentum to errant nuclei and their projections, pushing them around the liquid droplet to the shaded side. The close proximity of the substrate assures that there will be a large difference in ion and fast neutral fluxes between the concealed and exposed surfaces of the droplets even where the angular distribution of the incident flux is very broad, as it may be when the mean free path is quite short with respect to the plasma sheath. In an embodiment, the alignment of the nanostructures is assisted by relatively intense bombardment of the mediating metal with ions and fast neutral particles of relatively low energies. When alignment control can be implemented by this means, the loss of mediating material by sputter etching may be reduced, and taller nanostructures may be grown. In other embodiments, both the ion etching scheme and the low energy bombardment scheme are used to control alignment, either simultaneously through a suitable choice of conditions, or sequentially, allowing the advantages of each to be employed during different phases of the growth process.

In an embodiment, irradiation of the mediating material and the substrate is accomplished by a combination of positively charged ions from a plasma and also by “fast neutrals” from a plasma. Fast neutrals are here defined as neutral atoms that are directed toward the substrate with energies exceeding 20 times the characteristic thermal energy of the neutral gas comprising the plasma. That characteristic thermal energy is given by the product of the Boltzman constant and the absolute temperature of the neutral gas. Fast neutrals may be generated by collisions between accelerated ions and neutral atoms or neutral molecules within the plasma sheath region surrounding the substrate.

In an embodiment, the average impact energy of ions striking the substrate surface during synthesis of the nanostructures is on the order of at least 5 eV. Under some conditions, this energy may be sufficient to provide some radiation-induced mixing at the mediating material surface. In an embodiment, the average impact energy of ions striking the substrate surface during synthesis of the nanostructures is on the order of at least 10 eV. It is believed that reactive etching can be obtained with an impact energy of 10 eV or so in a hydrogen-containing plasma, but there may be enough thermal energy in the hydrogen component of the plasma that a 10 eV beam extracted from the plasma will not be adequately collinear. That is, such a beam may have considerable lateral momentum, and may etch sidewalls of tall structures excessively, so higher impact energies may be desirable.

In other embodiments, the average impact energy of ions striking the substrate surface during synthesis of the nanostructures is on the order of at least 50 eV, 100 eV, 200 eV, 500 eV, 1.0 keV, 1.5 keV, 2.0 keV or 2.5 keV. In other embodiment, the average impact energy is from 50 eV to 1.5 keV, from 50 eV to 1.0 keV, from 50 eV to 500 eV, or from 50 eV to 200 eV. For structures with high aspect ratios, a highly collinear beam of ions is most able to affect the shapes of the structures over their entire lengths.

The average impact energy of ions striking the substrate surface during subsequent deposition on the nanostructures can also affect the resulting structure. In an embodiment, lower bombardment energies can lead to concentration of deposition at the tips of the nanostructures while higher bombardment energies can lead to deposition over a greater length of the nanostructure.

In one embodiment of the invention, the ions are supplied by a plasma generated in the vacuum chamber. In this aspect of the invention, a negative electric potential is imposed on the substrate relative to the plasma. The energy with which ions will bombard the substrate surface will depend in part upon the difference between the plasma potential and the substrate potential. In different embodiments, the applied potential is from 50 V to 1.5 kV, from 50 V to 1 kV, from 50 V to 500 V, from 50 V to 150 V, from 500 V to 1.5 kV or from 500 V to 1.0 kV.

The negative electric potential can be applied to the substrate using a power supply electrically connected between the substrate and the chamber, or between the substrate and other suitable electrodes within the chamber, or may be induced by the application of a radio-frequency (RF) potential onto the substrate with respect to other electrodes within the chamber. The principles of RF substrate bias are well known to those practiced in the art, and may be found in standard references (see appendix C-3 in Anner, G. E., Planar Processing Primer (1990), Van Nostrand Reinhold, New York). However, simply applying a voltage does not necessarily result in directed impact energy if collisions disrupt the trajectories of the attracted ions. For the full difference between the substrate potential and the plasma potential to appear as directed impact energy, the pressure must be low enough and the plasma sheath thin enough that collisions seldom occur as ions are accelerated from the plasma through the sheath and onto the substrate. Often, particularly as gas pressure is increased, this condition is not met, and charge-exchange collisions occur frequently in the sheath region, reducing the impact energies of particles striking the substrate, but increasing their numbers. This can be advantageous for obtaining intense low-energy bombardment of the mediating metal, as discussed above.

Without wishing to be bound by any particular belief, it is believed that in some embodiments, the potential applied between the substrate and the plasma can also influence the alignment of the growth through the influence of electrostatic forces upon the nanostructures. The application of a potential between the substrate and the plasma will result in mechanical forces that may act to extend the nanostructure in the direction of the field (see Philippe Poncharal, et al., 1999, Science, 283, 1513-1516). Since the field at the substrate surface is generally oriented parallel to the surface normal vector, the nanostructures, if mechanically compliant, can tend to extend along that direction. In addition to stretching out the already-grown nanostructure, this may influence the direction of ongoing growth (see Vladimir I. Merkulov, 2001, Applied Physics Letters 79(8), 1178-1180, also N. N. Dzbanovsky, 2006, Microelectronics Journal, 36, 634-638). In an embodiment, additional etching and deposition occur along the sides of the nanostructures while they are in this extended state, the stiffness of the added material helping to maintain the elongated state after the bias is removed. In another embodiment, ion and fast neutral irradiation of the extended nanostructures also serves to anneal them, so that, by the end of the processing period, the relaxed state of the nanostructures has become similar to the extended state existing under bias.

In an embodiment, the plasma is generated from a gas mixture comprising one or more noble gases, nitrogen, or combination thereof. In this embodiment, the noble gas, nitrogen, or combination thereof comprise the majority of the gas mixture. In different embodiments, the noble gas is argon, neon, or helium or combinations thereof. The gas may be chosen on the basis of its expected threshold energy for sputtering of the mediating material.

Other gases may also be present in the mixture, either as impurities or deliberately added to the mixture. Water vapor is typically the major constituent of residual vacuum in unbaked vacuum systems. In a system with a base pressure of 8×10⁻⁷ Torr, the water vapor partial pressure may typically be as high as 5×10⁻⁷ Torr. Water vapor may also be deliberately added. In an embodiment, the amount of water vapor added is below that at which the sputtering target and sample surfaces start to become oxidized. For example, water vapor may be present in quantities less than 1%, than 0.5% or about 0.1%. In another embodiment, the water vapor pressure is less than 1×10⁻⁴ Torr, or about 1×10⁻⁵ Torr. In another embodiment, a silicon dioxide sputtering target is used in addition to the water vapor. The addition of water to the gas mixture can increase the fraction of droplets that yield elongated nanostructures and also increase the average growth rate of the projections. The concentration of water vapor may be adjusted depending on the growth rate, with lower concentrations being employed at lower growth rates and higher concentrations at higher growth rates.

In an embodiment, the plasma is generated from a gas mixture comprising hydrogen and an inert gas such as argon. In different embodiments, the percentage of hydrogen in a hydrogen/argon mixture is between 5% and 15% or about 10%. In another embodiment, the gas mixture comprises hydrogen, a noble gas, and water vapor. In another embodiment, hydrogen is not deliberately added to the gas mixture and is present only in trace amounts.

In another embodiment, the gas mixture comprises nitrogen as a minor component in combination with a noble gas such as argon.

In an embodiment, argon is the major constituent of the plasma environment, indium or tin is used as the mediating metal, and the average impact energy of the ions is selected to be less than 1.4 keV. In another embodiment, argon is the major constituent of the plasma environment, indium is used as the mediating metal, and the average impact energy of the ions is less than 200 eV. In another embodiment, helium is the major constituent of the plasma environment, indium or tin is used as the mediating metal, and the average impact energy of the ions is less than 200 eV.

To compensate for the sputtering of the mediating metal which can occur at the substrate, mediating material can be co-deposited or sequentially deposited with the nanostructure material. For example, half of a silicon magnetron surface can be covered with an indium foil, resulting in the co-deposition of indium and silicon. In another embodiment, separate magnetrons are used for each element. For example, rotating or otherwise sequenced shutters can be used over the magnetrons, the depositions performed cyclically, and the sample bias applied only during the phase when both magnetrons are covered.

A variety of techniques are known in the art for forming plasmas, including injecting beams of microwaves and introducing magnetic or electric fields into a low pressure gas. In an embodiment, the plasma is not generated via microwaves. In an embodiment, the plasma is generated by applying a potential difference between electrodes. The substrate potential may or may not significantly excite the plasma. Any reactor configuration known to the art may be used, including diode and triode reactors. In an embodiment, the plasma is formed by a sputtering source in which the cathode is a target of the material to be sputtered. In magnetron sputtering sources, one or more magnets provide a magnetic field in the vicinity of the cathode surface. In this configuration, the side walls of the system can act as the anode. In an embodiment, a magnetic field is arranged in the vicinity of the substrate, serving to enhance the plasma density in the plasma region from which ions are extracted to bombard the sample, thus increasing the attainable bombardment flux for a given pressure and substrate potential. In another embodiment, a planar hollow cathode geometry is employed. For example, two substrates may be placed opposite each other, separated by a distance on the order of a few times the mean free path. With both substrates biased quite negatively with respect to the nearby chamber walls, a planar hollow cathode will be formed, allowing larger discharge currents (hence more rapid growth rates) than an isolated wafer can support. Magnetic fields may again be used to increase the plasma density in the region near the samples. In this configuration, silicon and indium removed from one sample will likely land on the other, reducing waste as the growth proceeds. The feedstock can be Si predeposited on the wafer or silane in the gas phase, or both. Gas chemistry can include silane, Ar as a diluent, and H₂. Note that the two substrates can be sections of a continuous web (or two webs) passing through a reaction zone, and each can pass over a large-radius, temperature controlled roller or sliding surface to provide the almost-planar conditions desired.

In an embodiment, the substrate and growing nanostructures are bombarded by an ion beam. In an embodiment, the ion beam is provided by an ion gun. In an embodiment, the ion beam comprises ions selected from the group consisting of H, He, Li, N, O, Ne, Na, Ar. In different embodiments, the ion beam provides hydrogen ions or helium ions. The beam divergence, measured as the ratio of the mean lateral ion velocity to the mean longitudinal ion velocity at impact is preferably less than or equal to the aspect ratio (base radius divided by height) of the nanostructures to be grown. During growth of the nanostructures, the pressure in the vacuum chamber is continuously maintained such that the mean free path of the ions is on the order of, and preferably at least ten times larger than, the distance traversed by the ions in passing from the ion source to the substrate surface. The higher the pressure, the greater the likelihood of collisions disrupting the trajectories of the ions. In this embodiment, suitable sources of the selected material include a layer of the selected material deposited on the substrate prior to deposition of the mediator layer. The selected material will then be sputtered by the ion beam and provide a source of the selected material for incorporation into the nanostructures. Alternately, an evaporator can be used to provide the selected material continuously during growth. If the ion gun is located sufficiently close to the substrate a low pressure of a precursor gas can supply the selected material without obstructing the ion flux with excessive collisions. If material is supplied by an evaporator or from a precursor, the pressure in the vacuum chamber is an important parameter. The action of the ion beam may be stopped when the desired height of nanostructures is reached, or when the coating of selected material on the substrate surface has been exhausted.

In another embodiment, the ions may be obtained by ion extraction from a slot in the wall of an inductively coupled plasma (ICP). The wall allows separation between the large RF fields in the ICP section and the ion acceleration section facing the substrate (Stumpe, E. et al., 1979, Appl. Phys. 20, 55-60).

The length and morphology of the nanostructures depends on the process conditions. When the ions are able to sputter the mediating material, sputtering of the mediating material particles can limit the length of the nanowires which can be obtained. Sputtering of the mediating material can also be reduced by adjusting the sputtering conditions, including the plasma composition and the potential applied to the substrate. Longer nanowires can be obtained when mediating metal is co-deposited with the nanostructures. Codeposition of mediating metal with the feedstock (e.g. silicon) can also result in the formation of nanocones, rather than cylindrical nanowires. Codeposition of more mediating metal can result in broader and stouter cones. The shape of the nanostructures is also influenced by the amount of deposition along the sidewalls of the nanostructures during synthesis. The ion-assisted VLS-type process has been demonstrated to produce both wire-like and cone-shaped structures, as described in U.S. Provisional Application 60/811,033 filed Jun. 5, 2006.

In an embodiment, the growth rate of the nanostructures is from 1 nm/min to about 1000 nm/min. Typically, the growth rate is on the order of 100 to 200 nm/min.

If desired, any mediating metal remaining at the top of the nanostructure can be sputtered away in a subsequent process step. For example, ions of an inert gas such as argon can be generated in the plasma and used for sputtering. As another example, hydrogen ions with sufficiently high energy can be used to sputter away the mediating material. Other ions, such as silane ions, can also be used. The metal can also be removed by other techniques such as chemical etching or reactive ion etching. Under some growth conditions or combinations of mediating materials and selected compositions of nanostructures, mediating material can be made to be incorporated within the growing structures. Other methods of mediating material removal include chemical vapor or plasma etching, as occurs, for example, when tin is exposed to hydrogen or hydrogen-containing vapors within the plasma, forming volatile tin hydrides.

In an embodiment, the nanostructure arrays produced by ion-assisted VLS can be modified by addition of material on the nanostructures. Chemical vapor deposition or physical vapor deposition techniques may be used. In one aspect of the invention, any remaining droplets of mediating material are not removed before this deposition step. In an embodiment, the mediating material is held at a temperature below the melting temperature before further deposition processing. In another aspect of the invention, the mediating material is removed from the nanostructures before further deposition processing or the mediating material is held at a temperature below the melting temperature before further deposition processing. In another aspect of the invention, the vacuum atmosphere is controlled so that reactive etching is minimized during further deposition. In an embodiment, the hydrogen content in the gas environment is negligible. In an embodiment, the additionally deposited material may be amorphous.

The additional deposition may form a complete or nearly complete layer of material on the nanostructures. In an embodiment, the nanostructures are not joined by the additionally deposited material, except perhaps at their bases, near the substrate. In this embodiment, the resulting structure also has the form of an array of nanostructures, although the resulting nanostructures may have a different shape than that of the initially synthesized nanostructures. For example, deposition may occur along the length of the nanostructures to form a conformal or nearly conformal coating on the nanostructures. In another embodiment, deposition may be distributed mainly toward the upper portion of the nanostructures. For example, silicon-containing nanocones can be made more cylindrical in shape by depositing an additional silicon layer such that silicon is preferentially deposited toward the upper portion of the nanocones. In another embodiment, the resulting structures are wider near their tips than near the substrate. In an embodiment, the process conditions are controlled to maintain an approximately fixed ratio between the average volume occupied by the nanostructures and the average volume represented by the voids between them.

All patents and publications mentioned in the specification are indicative of the levels of skill of those skilled in the art to which the invention pertains. References cited herein are incorporated by reference herein in their entirety to indicate the state of the art, in some cases as of their filing date, and it is intended that this information can be employed herein, if needed, to exclude (for example, to disclaim) specific embodiments that are in the prior art. For example, when a method is claimed, it should be understood that methods known in the prior art, including certain methods disclosed in the references disclosed herein (particularly in referenced patent documents), are not intended to be claimed. All references cited herein are hereby incorporated by reference to the extent that there is no inconsistency with the disclosure of this specification. Some references provided herein are incorporated by reference herein to provide details concerning additional starting materials, additional methods of synthesis, additional methods of analysis and additional uses of the invention.

One skilled in the art would readily appreciate that the present invention is well adapted to carry out the objects and obtain the ends and advantages mentioned, as well as those inherent therein. The methods and accessory methods described herein as presently representative of preferred embodiments are exemplary and are not intended as limitations on the scope of the invention. Changes therein and other uses will occur to those skilled in the art, which are encompassed within the spirit of the invention, are defined by the scope of the claims.

Although the description herein contains many specificities, these should not be construed as limiting the scope of the invention, but as merely providing illustrations of some of the embodiments of the invention. Thus, additional embodiments are within the scope of the invention and within the following claims.

As used herein, “comprising” is synonymous with “including,” “containing,” or “characterized by,” and is inclusive or open-ended and does not exclude additional, unrecited elements or method steps. As used herein, “consisting of” excludes any element, step, or ingredient not specified in the claim element. As used herein, “consisting essentially of” does not exclude materials or steps that do not materially affect the basic and novel characteristics of the claim. Any recitation herein of the term “comprising”, particularly in a description of components of a composition or in a description of elements of a device, is understood to encompass those compositions and methods consisting essentially of and consisting of the recited components or elements. The invention illustratively described herein suitably may be practiced in the absence of any element or elements, limitation or limitations which is not specifically disclosed herein.

When a Markush group or other grouping is used herein, all individual members of the group and all combinations and subcombinations possible of the group are intended to be individually included in the disclosure.

The terms and expressions which have been employed are used as terms of description and not of limitation, and there is no intention in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments and optional features, modification and variation of the concepts herein disclosed may be resorted to by those skilled in the art, and that such modifications and variations are considered to be within the scope of this invention as defined by the appended claims.

In general the terms and phrases used herein have their art-recognized meaning, which can be found by reference to standard texts, journal references and contexts known to those skilled in the art. The preceding definitions are provided to clarify their specific use in the context of the invention.

1. A photovoltaic cell comprising:
a. a first and a second electrical contact layer, at least one of the first and second contact layer being transparent; and
b. a nanostructured thin film comprising
a secondary array of elongated nanostructures comprising a first and a second type of semiconducting material; and
an intermediate layer of the first type of semiconducting material in contact with the first contact layer,
wherein the nanostructures of the secondary array comprise a primary array of elongated nanostructures comprising the first type of semiconducting material, the primary array being at least partially coated by a layer of the second type of material, the first semiconducting material of the primary array contacts the intermediate layer, but not the first contact layer or the second contact layer, the second semiconducting material contacts the second contact layer, but not the first contact layer, the maximum width of each nanostructure of the secondary array is between about 2 nanometers and about 1 micrometer, the nanostructures of the secondary array are aligned so that their longitudinal axes are generally normal to the surface of the first contact layer and the first type of semiconducting material has a room temperature band gap less than or equal to 3 eV.

2. The cell of claim 1, wherein the intermediate layer is continuous and the second contact layer is optically transparent.

3. The cell of claim 2, wherein the layer of the second semiconducting material is continuous.

4. The cell of claim 3, wherein the nanostructures of the secondary array are broader at their bases than their tips, the bases of these nanostructures cover the surface of the intermediate layer and the second contact layer is a continuous layer attached to the layer of the second semiconducting material.

5. The cell of claim 3, wherein only a portion of the layer of the second semiconducting material contacts the second contact layer and the cell further comprises a layer of transparent electrically insulating material, the layer of insulating material being attached to the portions of the layer of the second semiconducting material not attached to the second contact layer.

6. The cell of claim 2, wherein the layer of the second semiconducting material is discontinuous and attached to the top portions of the nanostructures of the primary array and only a portion of the layer of the second semiconducting material contacts the second contact layer.

7. The cell of claim 6, further comprising a layer of transparent insulating material attached to the portions of the layer of the second semiconducting material not attached to the second contact layer and attached to the portions of the surfaces of the nanostructures of the primary array which are not attached to the layer of the second semiconducting material.

8. The cell of claim 1, wherein the intermediate layer and the layer of the second semiconducting material are both discontinuous and only a portion of the layer of the second semiconducting material contacts the second contact layer.

9. The cell of claim 8, further comprising a layer of transparent insulating material attached to the portions of the first contact layer not covered by the intermediate layer, the uncoated portions of the surface of the nanostructures of the primary array, and the portions of the layer of the second semiconducting material which are not attached to the second contact layer.

10. The cell of claim 1, wherein the nanostructures of the primary array consist essentially of a semiconducting material.

11. The cell of claim 1, wherein the nanostructures of the primary array comprise a doped semiconducting material surrounded by a shell of an intrinsic semiconducting material.

12. The cell of claim 1, wherein the nanostructures of the primary array comprise a core of an insulating material surrounded by a shell of a semiconducting material.

13. The cell of claim 1, wherein the first semiconducting material is one of an n-type or p-type semiconductor and the second semiconducting material is the other of n-type or p-type semiconductor.

14. The cell of claim 13, wherein the first and second material are both doped silicon.

15. A photovoltaic cell comprising:
a. a first and a second electrical contact layer, at least one of the first and second contact layer being transparent; and
b. a nanostructured thin film comprising
a secondary array of elongated nanostructures comprising a first and a second type of semiconducting material; and
a layer of an optically transparent insulating material
wherein the nanostructures of the secondary array comprise a primary elongated nanostructure array comprising the first type of semiconducting material, the primary array being at least partially coated by a layer of the second type of semiconducting material, the first semiconducting material of the primary array of nanostructures contacts at least a portion of the first contact layer, but does not contact the second contact layer, the second semiconducting material contacts a portion of the second contact layer, but does not contact the first contact layer, the layer of transparent insulating material is attached to the portions of the nanostructures of the secondary array which are not in contact with either the first or second contact layer and the portions of the second contact layer which are not in contact with the second layer of semiconducting material, the maximum width of each nanostructure of the secondary array is between about 2 nanometers and about 1 micrometer, and the nanostructures of the secondary array are aligned so that their longitudinal axes are generally normal to the surface of the first contact layer.

16. The cell of claim 15, wherein the nanostructures of the secondary array are broader at their bases than their tips and the bases of these nanostructures cover the surface of the first contact layer.

17. The cell of claim 16, wherein the layer of the second type of material is continuous.

18. The cell of claim 16, wherein the layer of the second type of semiconducting material is discontinuous.

19. The cell of claim 15 wherein the top surface of the first contact layer is partially covered by the bases of the nanostructures of the secondary array, the layer of transparent insulating material is attached to the remainder of the top surface of the first contact layer and the layer of the second semiconducting material is discontinuous.

20. The cell of claim 15, wherein the nanostructures of the primary array consist essentially of a semiconducting material.

21. The cell of claim 15, wherein the nanostructures of the primary array comprise a doped semiconducting material surrounded by a shell of an intrinsic semiconducting material.

22. The cell of claim 15, wherein the nanostructures of the primary array comprise a core of an insulating material surrounded by a shell of a semiconducting material.

23. The cell of claim 15, wherein the first semiconducting material is one of an n-type or p-type semiconductor and the second semiconducting material is the other of n-type or p-type semiconductor.

24. The cell of claim 23, wherein the first and second material are both doped silicon.

25. A method for making a nanostructured solar cell comprising the steps of:
a. providing an electrically conducting substrate
b. depositing a continuous intermediate layer of a first type of semiconducting material on the upper surface of the conducting substrate;
c. forming a primary array of substantially aligned elongated nanostructures on the upper surface of the intermediate layer, the nanostructures of the primary array comprising the first type of semiconductor;
d. forming a layer of a second type of semiconducting material which at least partially coats the nanostructures of the primary array; thereby forming a secondary array
e. depositing a layer of transparent conducting material such that the layer of conducting material is at least partially in contact with the layer of the second type of semiconductor but is not in contact with the nanostructures of the primary array or the intermediate layer.

26. The method of claim 25, wherein the primary array of nanostructures is formed using an ion-assisted vapor-liquid-solid process.

27. The method of claim 25, wherein the primary array of nanostructures is formed using an ion-assisted vapor-liquid-solid process to make a first array followed by deposition of additional material on the first array to form a primary array.

28. The method of claim 25, wherein the method further comprises the step of depositing a layer of transparent insulating material prior to step d, the layer attached to portions of the nanostructures of the secondary array which are not in contact with the intermediate layer and the portions of the intermediate layer which are not in contact with the nanostructures of the secondary array.
